(19) United States
(12) Patent Application Publication
(10) Pub. No.: US 2024/0011160 A1
(43) Pub. Date: Jan. 11, 2024

(54) THIN FILM DEPOSITION WITH IMPROVED CONTROL OF PRECURSOR

(71) Applicant: Taiwan Semiconductor Manufacturing Company, Ltd., Hsinchu (TW)

(72) Inventors: Wen-Hao Cheng, Taichung City (TW); Hsuan-Chih Chu, Changhua Conty (TW); Yen-Yu Chen, Tauchung City (TW)

(21) Appl. No.: 17/811,876

(22) Filed: Jul. 11, 2022

(51) Int. Cl. C23C 16/52; C23C 16/455; C23C 16/34

(52) U.S. Cl. CPC C23C 16/52; C23C 16/45553; C23C 16/45544; C23C 16/34

(57) ABSTRACT

A precursor supply system for thin film deposition is provided. The precursor supply system includes a precursor source container, and the precursor source container includes: a top wall; a bottom wall; a side wall circumferentially connecting the top wall and the bottom wall, wherein at least a portion of an interior surface of the precursor source container has a three-dimensional (3D) pattern; an inlet configured to allow introduction of a carrier gas into the precursor source container; and an outlet configured to allow exit of a precursor vapor generated in the precursor source container.

### FIELD

Embodiments of the present disclosure relate generally to thin film deposition, and more particularly to atomic layer deposition (ALD).

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various thin film layers. The areas of the thin film that are to be deposited or removed are controlled through photolithography. Each of the deposition and removal processes is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating an example thin film deposition system in accordance with some embodiments.

FIG. 2A is a schematic diagram illustrating an example precursor supply system shown in FIG. 1 in accordance with some embodiments.

FIG. 2B is a schematic diagram illustrating a variation of the example precursor supply system shown in FIG. 2A in accordance with some embodiments.

FIG. 2C is a cross-sectional view of an example three-dimensional (3D) pattern in accordance with some embodiments.

FIG. 2D is a cross-sectional view of another example 3D pattern in accordance with some embodiments.

FIG. 2E is a cross-sectional view of a further example 3D pattern in accordance with some embodiments.

FIG. 2F is a top view of the example 3D pattern shown in FIG. 2C, in accordance with some embodiments.

FIG. 2G is a top view of the example 3D pattern shown in FIG. 2D, in accordance with some embodiments.

FIG. 2H is a top view of the example 3D pattern shown in FIG. 2E, in accordance with some embodiments.

FIG. 3 is a flowchart illustrating an example method of supplying a precursor source for thin film deposition in accordance with some embodiments.

FIG. 4A is a flowchart illustrating an example method of thin film deposition in accordance with some embodiments.

FIG. 4B is a flowchart illustrating an example operation of the method shown in FIG. 4A in accordance with some embodiments.

FIG. 5A illustrates an example of a pre-established operation model in accordance with some embodiments.

FIG. 5B illustrates the effect of an implementation of the present method in accordance with some embodiments.

FIG. 6 is a schematic diagram illustrating an example thin film produced by the present thin film system in accordance with some embodiments.

### DETAILED DESCRIPTION OF THE DISCLOSURE

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

Overview

Vapor deposition, such as chemical vapor deposition (CVD) and atomic layer deposition (ALD), is a powerful tool to produce thin films of materials for semiconductor device manufacturing. Generation and supply of a stable precursor vapor with a steady concentration from a condensed precursor source is critically important to the overall quality of the deposited thin film. Traditionally, solid precursor sources are stored in a container having a flat or substantially flat inner surface with limited contact area with the precursor source stored therein. When the container is heated, the heat may not be uniformly transferred to the precursor source due to the limited contact area, which may further cause fluctuating or unstable concentration of the precursor vapor generated from the solid precursor source and ultimately cause nonuniform thickness and/or poor coverage of the resulted thin film. In addition, there is a lack of real-time control of the precursor vapor quality in the container where the precursor vapor is generated. Thus, it is challenging to control the precursor vapor concentration and maintain it within a desired range for a target quality of the thin film.

In accordance with some aspects of the disclosure, novel precursor source containers, precursor supply systems, thin film deposition systems, and related methods are provided. In some implementations, a precursor source container includes a top wall, a bottom wall, a side wall circumferentially connecting the top wall and the bottom wall, an inlet configured to allow introduction of a carrier gas into the precursor source container, and an outlet configured to allow exit of a precursor vapor generated in the precursor source container. At least a portion of an interior surface of the precursor source container has a three-dimensional (3D) pattern. The 3D pattern includes a plurality of area enlarging elements configured to enlarge the total contact area between the interior surface of the precursor source container and the precursor source stored therein.

Compared with the traditional container without the 3D pattern, the present precursor source container could advantageously enhance the efficiency of heat transfer to the precursor source; enhance the phase transition of the precursor source from a condensed phase to a vapor phase; improve the thermal uniformity of the precursor vapor; improve the stability of the precursor vapor; reduce or minimize the formation of large clusters or aggregates of the precursor source material in the vapor phase; and maintain the concentration of the precursor vapor in a desired range for the target thin film.

In some implementations, the present precursor supply system further includes a precursor control unit operably connected to the precursor source container. The precursor control unit advantageously detects and monitors real-time operational parameters of the precursor source container such as temperature, concentration of precursor vapor, and the consumption of the precursor source and transmits these real-time operational parameters to a computing system. The precursor control unit could further receive an instruction containing a real-time adjustment signal from the computing system; adjust the operational parameter(s) of the precursor supply system in situ according to the instruction; and maintain a high quality of the precursor vapor to be used for thin film deposition.

Example Thin Film Deposition System

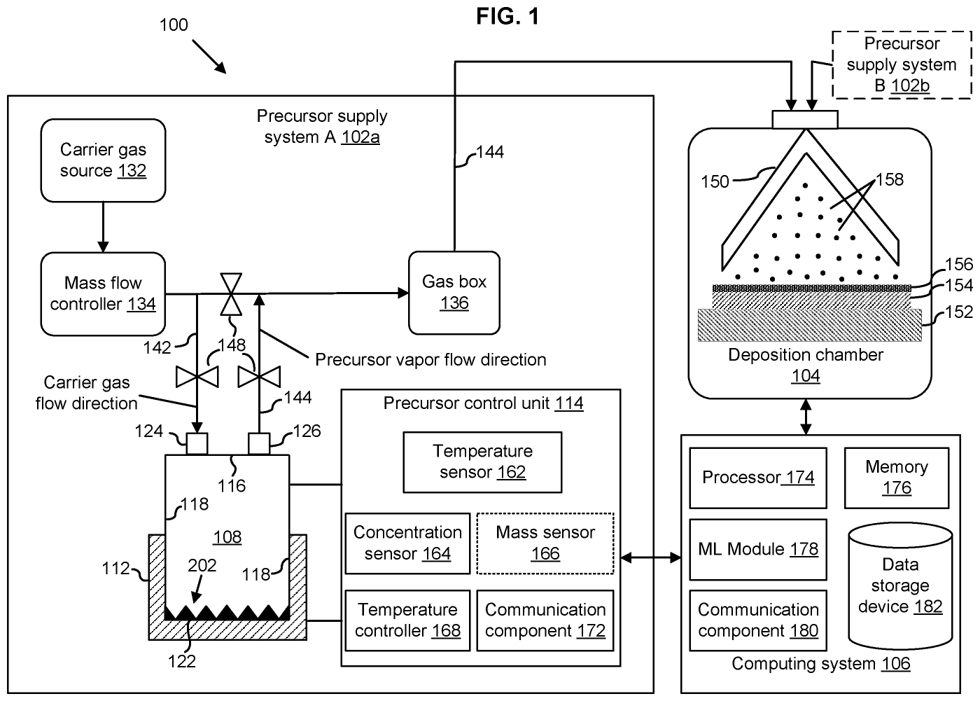

FIG. 1 is a diagram illustrating an example thin film deposition system 100 in accordance with some embodiments. It should be understood that the thin film deposition system 100 and various components thereof are exemplary rather than limiting. One of ordinary skill in the art would recognize many variations, modifications, and alternatives within the contemplation of the present disclosure. It should also be understood that FIG. 1 is not drawn to scale.

The thin film deposition system 100 is generally used in semiconductor manufacturing processes, particularly vapor deposition processes, in which the target material goes from a condensed phase (e.g., a solid phase, a semi-solid phase, or a liquid phase) to a vapor phase and then back to a thin film condensed phase on a substrate. Non-limiting examples of the thin film deposition described herein include physical vapor deposition (PVD), chemical vapor deposition (CVD), metalorganic chemical vapor deposition (MOCVD), atomic layer deposition (ALD), and vapor phase epitaxy (VPE), and variations or modifications thereof.

In the illustrated example of FIG. 1, a thin film deposition system 100 includes, among other components, at least one precursor supply system 102 (e.g., precursor supply system A 102a, precursor supply system B 102b, . . . , collectively as 102), a deposition chamber 104, and a computing system 106. The precursor supply system 102 is configured to generate and supply a precursor vapor or a gaseous precursor from a precursor source (e.g., precursor source A) to the deposition chamber 104. The deposition chamber 104 is generally configured to receive the precursor vapor, which is allowed to undergo chemical or physical interaction with the surface of a substrate placed in the deposition chamber 104, thereby forming a layer of the precursor source in a condensed phase on the substrate. The computing system 106 is in electrical communication with the at least one precursor supply system 102 and/or the deposition chamber 104 and configured to receive real-time signals of operational parameters or operational characteristics and to transmit real-time instructions to the at least one precursor supply system 102 and/or the deposition chamber to the guide operation of the thin film deposition system 100.

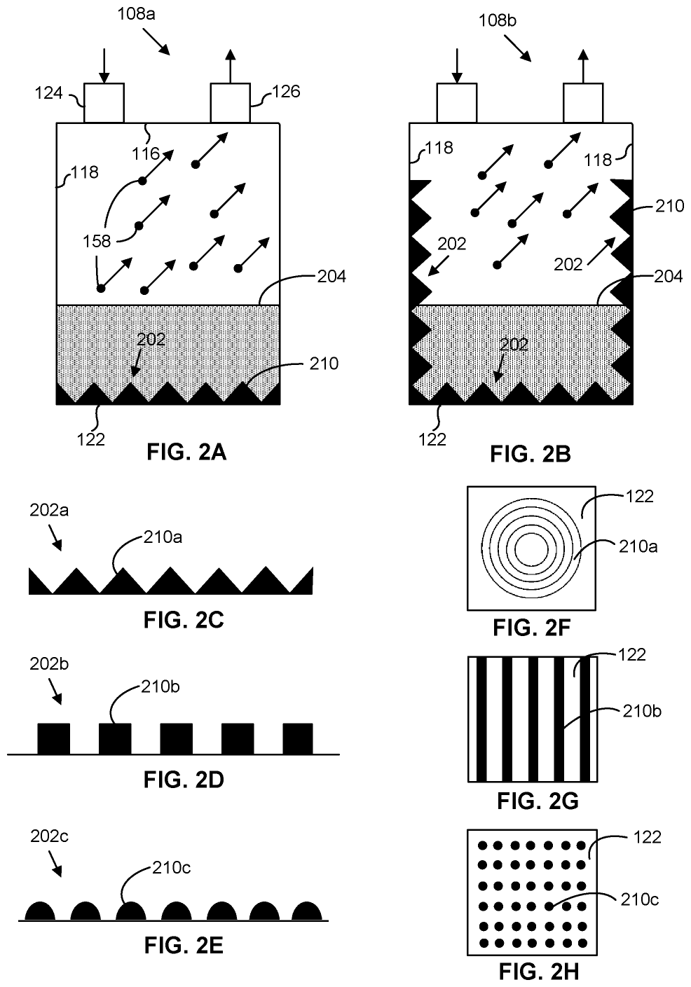

In some implementations, each of the at least one precursor supply system 102 includes, a precursor source container 108 configured to store a precursor source therein and generate a precursor vapor from the precursor source to be supplied to the deposition chamber 104. The precursor source container 108 can be of any desirable shape or size, for example, is cylindrical in shape and sized to fit within the existing space of a fabrication area. The precursor source container 108 includes a top wall 116, a side wall 118, and a bottom wall 122. The side wall 118 circumferentially connects the top wall 116 and the bottom wall 122, defining an interior space to store the precursor source and the precursor vapor generated from the precursor source. The precursor source container 108 further includes an inlet 124 and an outlet 126 separately mounted on the top wall 116. The inlet 124 is configured to allow introduction of a carrier gas into the precursor source container 108. The outlet 126 is configured to allow exit of a precursor vapor generated in the precursor source container 108. The precursor source container 108 includes a three-dimensional (3D) pattern 202 on at least a portion of an interior surface thereof. Examples of the three-dimensional (3D) pattern 202 are illustrated in FIGS. 2A-2E and will be described infra.

In some implementations, the precursor supply system 102 further includes a heating element 112 in heat communication with the precursor source container 108. The heating element 112 is configured to generate heat from a heat source and irradiate heat toward at least a portion of an exterior surface of the precursor source container 108. The heating element 112 may be in contact or proximity with at least a portion of the top wall 116, at least a portion of the bottom wall 122, or at least a portion of the side wall 118, or any combinations thereof. Non-limiting examples of the heating element 112 include an electrical heat source, a furnace, an infrared heat source, a heat tape, or any combinations thereof. The heat transferred into the interior space of the precursor source container 108 promote evaporation or sublimation of the precursor source or otherwise transform at least a portion of the precursor source from a condensed matter phase into a gaseous phase.

In some implementations, the precursor supply system 102 further includes a carrier gas source 132 and a mass flow controller (MFC) 134. The carrier gas source 132 is configured to provide a carrier gas that flows into the MFC 134. The carrier gas source 132 may be a vessel, such as a gas storage tank, that is located either locally to the precursor source container 108 or else may be located remotely from the precursor source container 108. The carrier gas may be an inert gas or other gas that does not react with the precursor source or other materials within the thin film deposition system 100. For example, the carrier gas may be argon (Ar), helium (He), nitrogen (N₂), hydrogen (H₂), any combinations thereof, and so on, although any other suitable carrier gas may alternatively be utilized.

The mass flow controller (MFC) 134 is in gas communication with the carrier gas source and the inlet 124 of the precursor source container 108. The MFC 134 is configured to control the flow of the carrier gas to the precursor source container 108 through line 142 and, eventually, to the deposition chamber 104, thereby also helping to control the pressure within the precursor source container 108 and the deposition chamber 104. The MFC 134 may be, for example, a proportional valve, a modulating valve, a needle valve, a pressure regulator, or any combinations thereof, and so on. The carrier gas introduced into the precursor source container 108 is further mixed with the evaporated precursor source to form a precursor vapor or a gaseous precursor.

In some implementations, the precursor supply system 102 further includes a gas box 136 in gas communication with the outlet 126 of the precursor source container 108 through line 144. The gas box 136 is configured to buffer the precursor vapor, or control the pressure, or further stabilize, homogenize, and/or purify the precursor vapor before transporting it to the deposition chamber 104 through line 130. The precursor supply system 102 may further include devices 148 as valves, flow meters, flow sensors, and the like to control the delivery characteristics such as flow rate, pressure, flow ON/OFF, purge ON/OFF, of the carrier gas and the precursor vapor.

Now referring to FIGS. 2A-2E, examples of the precursor source container 108 and the three-dimensional (3D) pattern 202 will be illustrated and described. FIG. 2A illustrates a cross-sectional view of one example precursor source container 108a in accordance with some embodiments of the disclosure. FIG. 2B illustrates a cross-sectional view of another precursor source container 108b in accordance with some embodiments of the disclosure in accordance with some embodiments of the disclosure. FIGS. 2C-2E respectively illustrate cross-sectional views of example 3D patterns 202a, 202b, and 202c, in accordance with some embodiments of the disclosure. FIGS. 2F-2H respectively illustrate top views of the 3D patterns 202a, 202b, and 202c, in accordance with some embodiments of the disclosure.

In the illustrated example of FIG. 2A, the precursor source container 108a has a 3D pattern 202 on an interior surface of the bottom wall 122 and contains a precursor source 204 in contact with the 3D pattern 202. The 3D pattern 202 includes a plurality of area enlarging elements 210 configured to enlarge a total contact area of the interior surface of the precursor source container with the precursor source 204 stored therein. The area enlarging elements 210 may increase a total area of the interior surface of the precursor source container 108a by at least 10%, or at least 20%, or at least 30%, or at least 40%, or at least 50%, or at least 100%, or at least 150%, or at least 200%, or at least 500%, or at least 1,000%, relative an interior surface that is flat or substantially flat, or otherwise without the area enlarging elements 210. The area enlarging elements 210 are made of thermally conductive materials (e.g., metal). The enlarged contact area provided by the 3D pattern 202 can significantly enhance the efficiency of heat transfer to the precursor source and enhance the phase transition of the precursor source 204 from a condensed phase to a vapor phase, thereby improving the overall quality of the generated precursor vapor 158. In some implementations, use of the precursor source container 108a or 108b could improve stability and thermal uniformity of the generated precursor vapor 158, reduce or minimize the formation of large clusters or aggregates of the precursor source material in the precursor vapor 158, and maintain the concentration of the precursor vapor 158 in a target range.

In some embodiments, the 3D pattern 202, the top wall 116, the side wall 118, and the bottom wall 122 are built as one piece. In other embodiments, the 3D pattern 202 is detachably mounted to the bottom wall 122. The fact that the 3D pattern 202 is detachable increases the flexibility to upgrade existing precursor source containers with a substantially flat inner surface(s) in a cost-effective manner.

In some implementations, the precursor source 204 is pentakis-(DiMethylAmido) Tantalum (V) (PDMAT) in a powder form used to form a Ta-containing thin film in an ALD process. The PDMAT powder has an enlarged contact area with the 3D pattern 202 and thereby is heated more uniformly and efficiently, as compared with a conventional type of precursor source container without the 3D pattern 202. The PDMAT vapor may have a stable concentration in the precursor source container with a deviation of less than 20%, or less than 10%, or less than 5%, from the target PDMAT vapor concentration. In some implementations, the target PDMAT vapor concentration for deposition of a TaN thin film is from about 0.0002 to about 0.002 M, or from about 0.0005 to about 0.0015 M, or from about 0.0008 to about 0.001 M. In some implementations, the generate PDMAT vapor has a mono-dispersed particle size distribution with a content of clusters or aggregates less than about 20%, or less than about 15%, or less than about 10%, or less than about 5%. Other non-limiting examples of the precursor source include HfCl₄, Al(OC₃H₇)₃, Pb(OC(CH₃)₃)₂, Zr(OC(CH₃)₃)₄, Ti(OCH(CH₃)₂)₄, Ba(OC₃H₇)₂, Sr(OC₃H₇)₂, RuCp₂, WCl₅, and so on.

Another example precursor source container 108b, which is a close variation of the precursor source container 108a, is illustrated in FIG. 2B. In the illustrated example, the precursor source container 108b has a 3D pattern 202 located on both the side wall 118 and the bottom wall 122, which may further enlarge the contact area between the precursor source 204 and the 3D pattern 202.

The 3D pattern 202 may be of various shapes, sizes, and configurations. In some implementations, each area enlarging element is characterized by a cross-sectional shape that is substantially triangular (210a shown in FIG. 2C), substantially square or rectangular (210b shown in FIG. 2D), or substantially curved (210c shown in FIG. 2E), or any combinations thereof.

The slopes of the substantially triangular area enlarging elements 210a and the bottom wall 122 may define various angles (e.g., 15 degrees, 30 degrees, 45 degrees, 60 degrees, 75 degrees, etc.) in various embodiments. The substantially square or rectangular area enlarging elements 210b may have various pitches in various embodiments. Given the same size of the substantially square or rectangular area enlarging elements 210b, they can be arranged either densely (i.e., with a relatively smaller pitch) or sparsely (i.e., with a relatively larger pitch) in various embodiments. The substantially curved area enlarging elements 210c may have various curvatures in various embodiments. The substantially curved area enlarging elements 210c may also have various pitches in various embodiments. Given the same size of the substantially curved area enlarging elements 210c, they can be arranged either densely (i.e., with a relatively smaller pitch) or sparsely (i.e., with a relatively larger pitch) in various embodiments. One of ordinary skill in the art would recognize many variations, modifications, and alternatives.

The area enlarging elements 210 may have a continuous configuration that is substantially concentric (shown in FIG. 2F), a substantially parallel configuration (shown in FIG. 2G), or a discrete configuration (shown in FIG. 2H). In one example, the area enlarging elements 210 are arranged in multiple rows and multiple columns, forming an array thereof. One of ordinary skill in the art may appreciate any variations and modifications of the pattern 202 and the area enlarging elements 210 or the equivalent thereof.

Now referring back to FIG. 1, the precursor supply system 102 may further include a precursor control unit 114 in operable and controllable communication with the precursor source container 108. The precursor control unit 114 is configured to detect, monitor, and/or control at least one real-time operational parameter or characteristic of the precursor supply system 102. The real-time operational parameters or characteristics include but are not limited to quantity, temperature, concentration, flow rate, pressure, and so on.

In some implementations, the precursor control unit 114 includes, among other components, a temperature sensor 162, a concentration sensor 164, a temperature controller 168, and a communication component 172. The temperature sensor 162 is configured to detect and monitor the temperature of the precursor source container 108. The concentration sensor 164 is configured to detect and monitor the precursor vapor concentration in the precursor source container 108. The temperature controller 168 is operably connected to the heating element 112 and is configured to control the heating element 112 and adjust the temperature of the precursor source container in situ during operation.

In some implementations, the precursor control unit 114 may further include a mass sensor 166. The mass sensor 166 is configured to detect and monitor an unconsumed quantity (or weight) of the precursor source remaining in the precursor source container 108. Although the temperature sensor 162, the concentration sensor 164, and the mass sensor 166 are schematically illustrated to be located in the precursor control unit 114, it should be understood that they may be mounted inside, in contact with, or in close proximity to the precursor source container 108 in other implementations.

The communication component 172 is configured to transmit signals of the real-time operational parameters or characteristics, such as the detected temperature, the detected concentration of the precursor vapor, and/or the detected unconsumed quantity of the precursor source to the computing system 106 in situ during operation. The communication component 172 is further configured to receive one or more instructions from the computing system to guide the operation of the precursor supply system 102 in situ. In some implementations, the instruction has a real-time temperature adjustment signal based on a pre-established operation model for maintaining the precursor vapor concentration in a target range, and the temperature controller controls the heating element in situ based on the real-time temperature adjustment signal to maintain the precursor vapor concentration in the target range.

In the illustrated example of FIG. 1, the deposition chamber 104 includes, among other components, a showerhead 150, a substrate support 152 operable to support or accommodate a substrate 154. The showerhead 150 may be utilized to disperse the chosen precursor vapor into the deposition chamber 104 and may be designed to evenly disperse the precursor source in order to minimize undesired process conditions that may arise from uneven dispersal. In some implementations, the showerhead 150 may have a circular design with openings dispersed evenly around the showerhead 150 to allow for the dispersal of the desired precursor source into the deposition chamber 104.

However, as one of ordinary skill in the art will recognize, the introduction of precursor vapor(s) into the deposition chamber 104 through a single showerhead 150 or through a single point of introduction as described above is intended to be illustrative only and is not intended to be limiting to the embodiments. Any number of separate and independent showerheads 150 or other openings to introduce precursor sources into the deposition chamber 104 may alternatively be utilized. All such combinations of showerheads and other points of introduction are fully intended to be included within the scope of the embodiments.

The deposition chamber 104 may receive the desired precursor vapor(s) and expose the precursor source material(s) of the precursor vapor(s) to the substrate 154, and the deposition chamber 104 may be any desired shape that may be suitable for dispersing the precursor source material(s) and contacting the precursor source material(s) with the substrate 154. In some implementations, the deposition chamber 104 has a cylindrical side wall and a bottom. However, the deposition chamber 104 is not limited to a cylindrical shape, and any other suitable shape, such as a hollow square tube, an octagonal shape, or the like, may alternatively be utilized. Furthermore, the deposition chamber 104 may be surrounded by a housing (not shown) made of material that is inert to the various process materials. As such, while the housing may be any suitable material that can withstand the chemistries and pressures involved in the deposition process, in some implementations the housing may be steel, stainless steel, nickel, aluminum, alloys of these, combinations of these, and like.

Within the deposition chamber 104 the substrate 154 may be placed on a substrate support 152 in order to position and control the substrate 154 during the deposition process. The substrate support 152 may include heating mechanisms in order to heat the substrate 154 during the deposition process. Furthermore, while a single substrate support 152 is illustrated in FIG. 1, any number of substrate support 152 may additionally be included within the deposition chamber 104.

Additionally, the deposition chamber 104 and the substrate support 152 may be part of a cluster tool system (not shown). The cluster tool system may be used in conjunction with an automated handling system in order to position and place the substrate 154 into the deposition chamber 104 prior to the deposition process, position and hold the substrate 154 during the deposition process and remove the substrate 154 from the deposition chamber 104 after the deposition process. The deposition chamber 104 may also include an exhaust outlet (not shown) for exhaust gases to exit the deposition chamber 104.

In the illustrated example of FIG. 1, the computing system 106 includes, among other components, a processor 174, a memory 176, a machine learning (ML) module 178, a communication component 179, and a data storage device 182. The computing system 106 is generally configured to receive signals from the precursor control unit 114, process the signals, calculate a real-time adjustment value of an operational parameter or characteristic, transform the real-time adjustment value to an adjustment signal, and transmit the adjustment signals to the precursor control unit 114. The processor 174 is configured to process and analyze signals and execute instructions saved in the memory. The memory 176 is configured to store temporary variables or other intermediate information during signal processing by the processor 174.

The machine learning module 178 has a machine learning training algorithm configured to establish and improve an operational model for at least one operational parameter and/or a relationship between or among multiple operational parameters. The operational model may be trained by the machine learning module 178 based on a priori data generated from prior operations, with respect to a certain type of precursor source and/or in a certain type of precursor source container. The pre-established operation model generated by the machine learning module 178 can be used as a standard or reference for the processor to (1) determine whether an operational parameter is deviated from the standard or deviated from a target value or range based on the standard; (2) calculate the deviation value; (3) determine whether a real-time adjustment of the operational parameter is needed; and (4) determine the real-time adjustment value. During the operation of the thin film deposition system 100, if a real-time adjustment is needed, the computing system 106 will instantaneously transmit a real-time adjustment signal to the precursor control unit 114 in situ through, for example, the communication component 180 of the computing system 106.

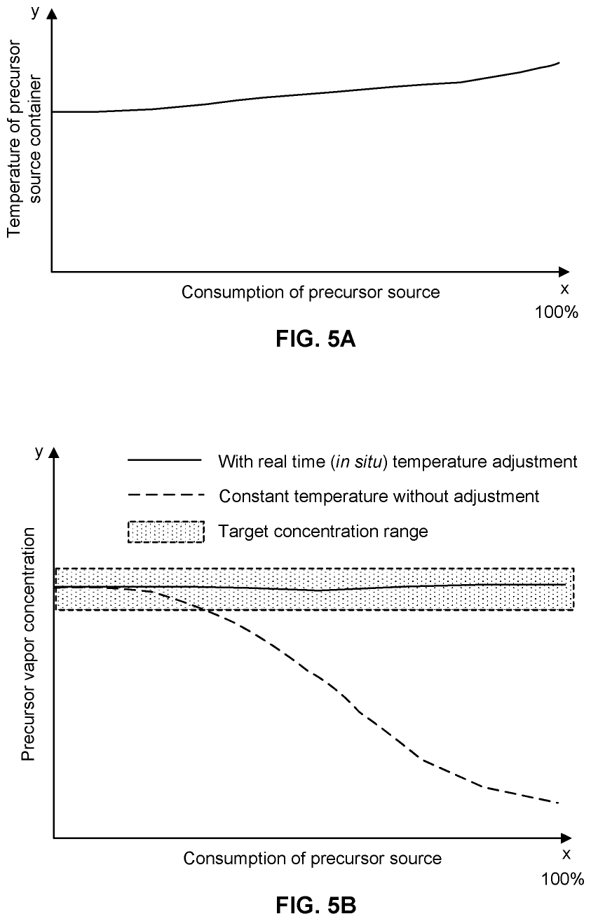

In some implementations, the pre-established operation model includes a mathematical profile describing the relationship between two operational parameters. Examples of the pre-established operation model are illustrated in FIGS. 5A-5B and will be described infra. The precursor control unit 114, in response to the received instruction, will adjust the operational parameter instantaneously to a target value or range. The data storage device 182 is configured to store any information related to the operation of the thin film deposition system 100, such as the real-time operational parameters or the pre-established operational model.

In some implementations, the computing system 106 is further in communication with a database through, for example, the communication component 180. The database may store any information related to the operation of the thin film deposition system 100, such as the real-time operational parameters or the pre-established operational model. The database may further store datasets (e.g., training datasets, testing datasets, etc.) accessible to the machine learning module 178, and the machine learning module 178 can be trained and tested based on these datasets accordingly.

In some implementations, the thin film deposition system 100 is an ALD system or configured to perform an ALD process. The ALD system may include at least 2, at least 3, at least 4, or at least 5 precursor supply systems configured to supply different precursor sources, respectively. The ALD system can be used to produce a variety of complex metal-containing compounds, such as metal oxides, metal nitrides, or other compounds having many main group metal elements and transition metal elements, such as aluminum, barium, cerium, dysprosium, hafnium, lanthanum, niobium, silicon, strontium, tantalum, titanium, tungsten, yttrium, zinc, and zirconium.

In some implementations, the thin film deposition system 100 includes at least two precursor supply systems 102a and 102b. The precursor supply system 102b is in gas communication with the deposition chamber 104 and is configured to generate and supply a precursor vapor B from a precursor source B to the deposition chamber 104. The precursor supply system 102b may have a similar or a different configuration compared with the precursor supply system 102a.

In one example implementation of the ALD system, the precursor vapors respectively from the precursor sources A and B are sequentially applied to the substrate in the deposition chamber with each pulse of precursor vapors separated by a purge. Each application of the precursor is intended to result in up to a single monolayer of the precursor source being deposited on the surface. These monolayers are formed because of the self-terminating surface reactions between the precursors and surface. In a particular implementation, the precursor source A supplied by the precursor supply system 102a is PDMAT; and the precursor source B supplied by the precursor supply system 102b is ammonia. The PDMAT vapor and ammonia vapor are supplied to the deposition chamber 104 in a sequential and alternating manner to allow for growing TaN thin film on a substrate according to the following mechanism:

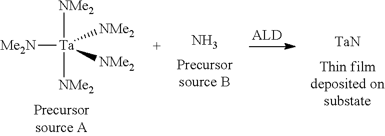

It should be understood that other Ta-containing thin films could also be produced by

the present thin film deposition system using PDMAT or equivalent thereof as the precursor source. Non-limiting examples of the Ta-containing thin films include TaNₓ, TaOₓ, TaCₓ, TaₓAl_{y}N_{z}, TaₓAl_{y}C_{w}N_{z}, and so on. The Ta-containing thin films may be used as, among others, barrier layer, resistor, capacitor, or other functional components for semiconductor devices.

Example Method for Thin Film Deposition

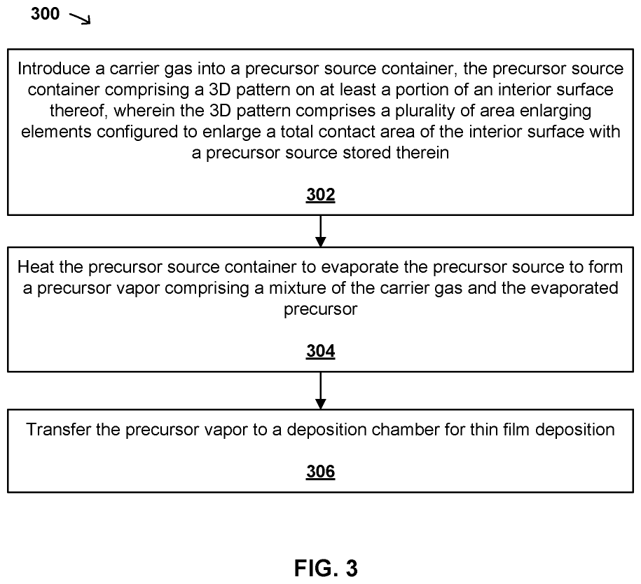

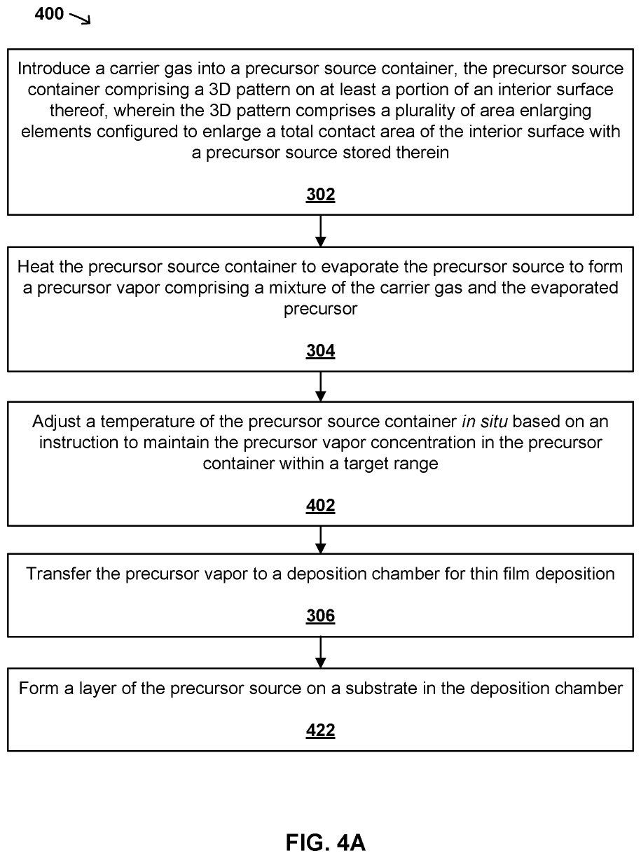

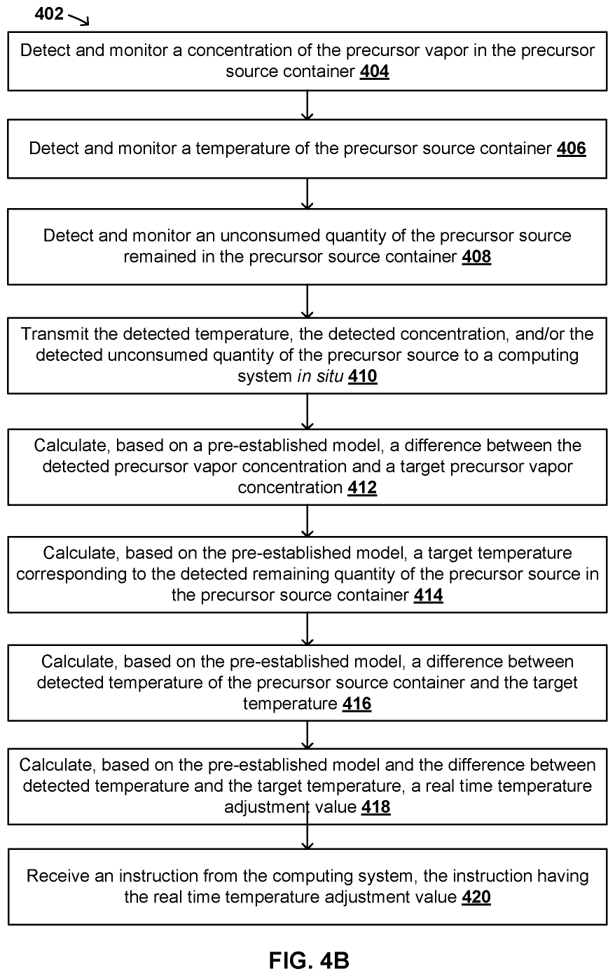

Now referring to FIGS. 3 and 4A-4B, example methods related to precursor source supply and thin film deposition for semiconductor manufacturing will be illustrated and described. FIG. 3 illustrates a flowchart of an example method of supplying a precursor source for thin film deposition in accordance with some embodiments of the disclosure. FIGS 4A illustrates an example method of thin film deposition in accordance with some embodiments of the disclosure. FIG. 4B illustrates a flowchart of one or more operations of the method shown in FIG. 4A.

In the illustrated example of FIG. 3, a method 300 includes operations 302, 304, and 306. Additional operations may be performed. Also, it should be understood that the sequence of the various operations discussed above with reference to FIG. 3 is provided for illustrative purposes, and as such, other embodiments may utilize different sequences. These various sequences of operations are to be included within the scope of embodiments.

At operation 302, a carrier gas is introduced into a precursor source container. In some implementations, the precursor source container includes a 3D pattern on at least a portion of an interior surface thereof, and the 3D pattern comprises a plurality of area enlarging elements configured to enlarge a total contact area of the interior surface with a precursor source stored therein. As discussed above, the 3D pattern improves the heat transfer efficiency through the enlarged contact area and improves the thermal uniformity and concentration stability of the precursor vapor generated in the precursor source container.

At operation 304, the precursor source container is heated to evaporate the precursor source to form a precursor vapor comprising a mixture of the carrier gas and the evaporated precursor.

At operation 306, the generated precursor vapor is transferred to a deposition chamber in gas communication with the precursor container for thin film deposition. In some implementations, the thin film deposition is ALD, and a plurality of precursor vapors correspondingly supplied by a plurality of precursor supply systems are transferred to the deposition chamber in a sequential and alternating manner for depositing alternating layers of respective precursor sources in the ALD process.

In the example shown in FIG. 4A, a method for thin film deposition includes

operations 302, 304, 402, 306, and 422. Additional operations may be performed. Also, it should be understood that the sequence of the various operations discussed above with reference to FIG. 4A is provided for illustrative purposes, and as such, other embodiments may utilize different sequences. These various sequences of operations are to be included within the scope of embodiments. Operations 302, 304, and 306 have been described above and will not be repeated here.

At operation 402, one or more operational parameters of the precursor supply system is adjusted in situ based on an instruction to maintain the precursor vapor concentration in the precursor container within a target range. In one embodiment, the operational parameter includes the real-time temperature of the precursor source container.

At operation 422, a layer of the precursor source is formed on a substrate in the deposition chamber. In some implementations, the thin film deposition is ALD, and alternating layers of two or more precursor sources are formed on the substrate in the ALD process, wherein each precursor source is supplied by the corresponding precursor supply system.

In the example shown in FIG. 4B, operation 402 may further include operations 404, 406, 408, 410, 412, 414, 416, 418, and 420. Additional operations may be performed. At operation 404, a concentration of the precursor vapor in the precursor source container is detected and monitored, for example, in situ, for example, by a precursor control unit shown in FIG. 1. At operation 406, a temperature of the precursor source container is detected and monitored, for example, in situ. At operation 408, an unconsumed quantity of the precursor source remaining in the precursor source container is detected and monitored, for example, in situ. At operation 410, the detected temperature, the detected concentration, and/or the detected unconsumed quantity of the precursor source are transmitted to a computing system, for example, in situ.

At operation 412, a difference between the detected precursor vapor concentration and a target precursor vapor concentration is calculated based on a pre-established operation model. At operation 414, a target temperature corresponding to the detected unconsumed quantity of the precursor source remaining in the precursor source container is calculated based on the pre-established operation model. At operation 416, a difference between the detected temperature of the precursor source container and the target temperature is calculated based on the pre-established operation model. At operation 418, a real-time temperature adjustment value is calculated based on the pre-established operation model and the difference between the detected temperature and the target temperature. In some implementations, the real-time temperature adjustment value may be in a range from about 0.1° C. to about 20° C., or from about 0.5° C. to about 10° C., or from about 1° C. to about 5° C., relative to the temperature prior to adjustment. In some implementations, the real-time temperature adjustment value may be in a range from about 0.1% to about 20%, or from 0.5% to about 10%, or from about 1% to about 5%, relative to the temperature prior to adjustment. Operations 412, 414, 416, and 418 may be performed by the computing system 106 of FIG. 1. In some implementations, operation 402 further includes transforming the real-time temperature adjustment value into a real-time temperature adjustment signal to be electrically transmitted to the precursor control unit 114 of FIG. 1.

FIG. 5A illustrates an example of the pre-established operation model, which is a temperature profile describing the target temperature (y-axis) of the precursor source container as a function of the consumption (x-axis; 0 to 100%) of the precursor source for maintaining the concentration of the precursor vapor in the precursor source container constant or within a target range. As shown in FIG. 5A, when consumption of the precursor source in the precursor source container is relatively low (e.g., 25% or less), the target temperature of the precursor source container may remain relatively stable and no adjustment is needed to keep the concentration of precursor vapor in the precursor source container constant or within a target range (e.g., about 0.00089 M for PDMAT in the precursor source container).

The target temperature of the precursor source container increases gradually along with the temperature profile as the consumption progresses. At some point, for example, when the consumption of the precursor source is significant (e.g., 50% or more) or approaching the end life of the precursor source (e.g., 80% or more), considerable adjustment of temperature is needed in order to maintain the concentration of precursor vapor constant or in the target range. As discussed above, the temperature profile may be obtained from a prior data from the same precursor source and/or the same type of precursor source container by the machine learning module 178 of FIG. 1 or the like and used as a standard or reference by the computing system 106 of FIG. 1 to calculate the real-time adjustment value in need.

FIG. 5B illustrates a precursor vapor concentration profile describing the precursor vapor concentration as a function of the consumption of the precursor source in the precursor source container. As shown in FIG. 5B, the target precursor vapor concentration (y-axis) could remain constant or within the target concentration range, even the consumption of the precursor source is close to 100% if a real-time temperature adjustment is performed such that the real-time temperature of the precursor source container follows the temperature profile shown in FIG. 5A during operation. As a comparison, if no real-time temperature adjustment is performed, the precursor vapor concentration either changes significantly or undergoes uncontrolled fluctuation, which ultimately affects the quality of the thin film formed in the deposition chamber.

Example Thin Film Deposited

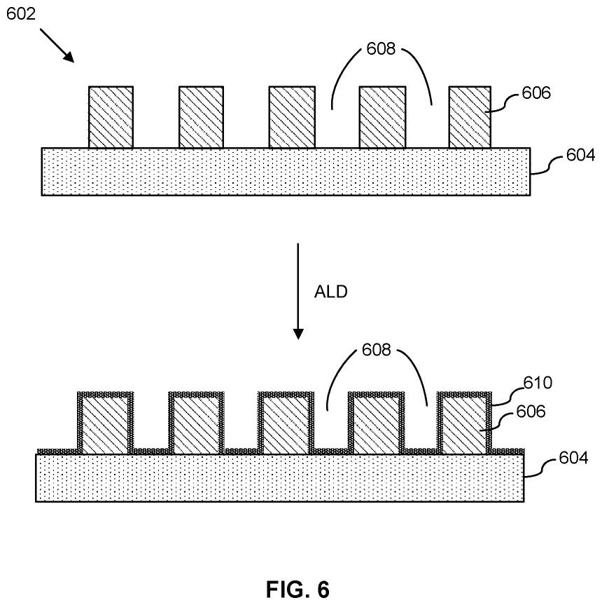

FIG. 6 is a schematic diagram illustrating an example thin film 156 produced by the present thin film deposition system or method. In the illustrated example, the thin film 156 is a TaN barrier layer formed on a semiconductor structure 602 using an ALD process by supplying PDMAT and ammonia vapor sources in a sequential and alternating manner according to some embodiments of the present disclosure. The semiconductor structure 602 includes, among other components, a semiconductor substrate 604 and an oxide layer (sometimes also referred to as an “intra-metal dielectric layer”) 606 formed on the semiconductor substrate. The oxide layer 606 is patterned and etched to form multiple trenches 608.

A thin film 610 (e.g., a TaN barrier layer) is formed on the semiconductor structure 602. The thin film 610 is formed on the bottom surface and the side walls of each of the multiple trenches 608, as shown in FIG. 6. Due to the stable concentration and thermal uniformity of the PDMAT vapor concentration achieved by the present ALD system, the thin film 610 has an improved thickness uniformity and covers the entire outer surface of the semiconductor structure 602. In one example, the thickness of the thin film 610 ranges from 0.5 nm to 1 nm.

In one example, the thin film 610 is a TaN barrier layer, which may be useful in the barrier/seed process. A seed layer (e.g., a Cu seed layer) is subsequently deposited on top of the TaN barrier layer. A conductive layer, such as a Cu layer, is subsequently formed using, for example, electro chemical plating (ECP). The excessive portion of the conductive layer outside the trenches 608 is removed using, for example, chemical-mechanical polishing (CMP). The TaN barrier layer prevents the conductive layer from penetrating into the oxide layer 606, whereas the seed layer facilitates the forming of the conductive layer. The improved coverage and thickness uniformity of the TaN barrier layer could provide better protection against copper diffusing into the oxide layer 606.

### SUMMARY

In accordance with some aspects of the disclosure, a precursor supply system for thin film deposition is provided. The precursor supply system includes a precursor source container, and the precursor source container includes: a top wall; a bottom wall; a side wall circumferentially connecting the top wall and the bottom wall, wherein at least a portion of an interior surface of the precursor source container has a three-dimensional (3D) pattern; an inlet configured to allow introduction of a carrier gas into the precursor source container; and an outlet configured to allow exit of a precursor vapor generated in the precursor source container.

In accordance with some aspects of the disclosure, a thin film deposition system is provided. The thin film deposition system includes: a first precursor supply system configured to generate and supply a first precursor vapor from a first precursor source, the first precursor supply system comprising a first precursor source container, wherein at least a portion of an interior surface of the first precursor source container has a three-dimensional (3D) pattern, wherein the 3D pattern comprises a plurality of area enlarging elements configured to enlarge a total contact area of the interior surface of the precursor source container with the first precursor source stored therein; and a deposition chamber in gas communication with the first precursor container, the deposition chamber configured to receive the first precursor vapor and deposit a layer of the first precursor source onto a substrate placed in the deposition chamber.

In accordance with some aspects of the disclosure, a method of for thin film deposition is provided. The method includes the following steps: introducing a carrier gas into a precursor source container, the precursor source container comprising a 3D pattern on at least a portion of an interior surface thereof, wherein the 3D pattern comprises a plurality of area enlarging elements configured to enlarge a total contact area of the interior surface with a precursor source stored therein; heating the precursor source container to evaporate the precursor source to form a precursor vapor comprising a mixture of the carrier gas and the evaporated precursor source; and transferring the precursor vapor to a deposition chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A precursor supply system for thin film deposition, the precursor supply system comprising a precursor source container, wherein the precursor source container comprises:
a top wall;
a bottom wall;
a side wall circumferentially connecting the top wall and the bottom wall, wherein at least a portion of an interior surface of the precursor source container has a three-dimensional (3D) pattern;
an inlet configured to allow introduction of a carrier gas into the precursor source container; and
an outlet configured to allow exit of a precursor vapor generated in the precursor source container.

2. The precursor supply system of claim 1, wherein the 3D pattern is located on at least a portion of the bottom wall, or at least a portion of the top wall, or at least a portion of the side wall, or any combinations thereof.

3. The precursor supply system of claim 1, wherein the 3D pattern comprises a plurality of area enlarging elements configured to enlarge a total contact area of the interior surface of the precursor source container with a precursor source stored therein.

4. The precursor supply system of claim 3, wherein the area enlarging elements increase a total area of the interior surface by at least 10%, or at least 20%, or at least 30%, or at least 40%, or at least 50%, or at least 100%, or at least 150%, or at least 200%, or at least 500%, or at least 1,000%, relative to the interior surface without the area enlarging elements.

5. The precursor supply system of claim 1, further comprising a heating element in proximity or contact with the precursor source container, the heating element configured to heat the precursor source container and evaporate a precursor source placed therein.

6. The precursor supply system of claim 5, further comprising a precursor control unit operably connected to the precursor source container, the precursor control unit comprising:
a concentration sensor configured to detect and monitor a real-time precursor vapor concentration in the precursor source container;
a temperature sensor configured to detect and monitor a real-time temperature of the precursor source container;
a mass sensor configured to detect and monitor a real-time unconsumed quantity of the precursor source remaining in the precursor source container; and
a temperature controller operably connected to the heating element, the temperature controller configured to control the heating element and adjust the temperature of the precursor source container in situ during operation.

7. The precursor supply system of claim 6, wherein the precursor control unit further comprises:
a communication component configured to:
transmit the real-time temperature, concentration of the precursor vapor, and/or unconsumed quantity of the precursor source to a computing system in situ during operation; and
receive an instruction from the computing system, the instruction having a real-time temperature adjustment signal based on a pre-established operation model for a target range of the precursor vapor concentration,
wherein the temperature controller controls the heating element in situ based on the instruction to maintain the precursor vapor concentration in the target range.

8. The precursor supply system of claim 5, further comprising a carrier gas source in gas communication with the inlet of the precursor source container, the carrier gas source configured to supply a carrier gas into the precursor source container, wherein the carrier gas is mixed with the evaporated precursor source to generate a precursor vapor in the precursor source container.

9. The precursor supply system of claim 8, further comprising a mass flow controller in gas communication with the carrier gas source and the inlet of the precursor source container, the mass flow controller configured to control flow rate and pressure of the carrier gas to be introduced into the precursor source container.

10. The precursor supply system of claim 1, further comprising a gas box in gas communication with the outlet of the precursor source container, the gas box configured to stabilize, purify, and homogenize the precursor vapor transferred therein.

11. A thin film deposition system, comprising:
a first precursor supply system configured to generate and supply a first precursor vapor from a first precursor source, the first precursor supply system comprising a first precursor source container, wherein at least a portion of an interior surface of the first precursor source container has a three-dimensional (3D) pattern, wherein the 3D pattern comprises a plurality of area enlarging elements configured to enlarge a total contact area of the interior surface of the precursor source container with the first precursor source stored therein; and
a deposition chamber in gas communication with the first precursor container, the deposition chamber configured to receive the first precursor vapor and deposit a layer of the first precursor source onto a substrate placed in the deposition chamber.

12. The thin film deposition system of claim 11, further comprising a heating element in heat communication with the precursor source container, the heating element configured to irradiate heat towards at least a portion of the precursor source container to evaporate a precursor source placed therein.

13. The thin film deposition system of claim 11, further comprising a precursor control unit in operable and controllable communication with the first precursor source container, the precursor control unit is configured to detect, monitor, and/or control at least one real-time operational parameter or characteristic of the first precursor supply system.

14. The thin film deposition system of claim 13, further comprising a computing system in electrical communication with the first precursor supply system, the computing system configured to receive signals from the precursor control unit, process the signals, calculate a real-time adjustment value of an operational parameter, transform the real-time adjustment value to an adjustment signal, and transmit the adjustment signals to the precursor control unit.

15. The thin film deposition system of claim 11, wherein the thin film deposition system is an atomic layer deposition (ALD) system.

16. The thin film deposition system of claim 15, further comprising a second precursor supply system configured to supply a second precursor vapor, wherein the first precursor vapor and the second precursor vapor are supplied to the deposition chamber in a sequential and alternating manner.

17. The thin film deposition system of claim 16, wherein the first precursor source includes pentakis(DiMethylAmido)Tantalum (V) (PDMAT), and wherein the second precursor vapor includes ammonia (NH₃).

18. A method of for thin film deposition, the method comprising:
introducing a carrier gas into a precursor source container, the precursor source container comprising a 3D pattern on at least a portion of an interior surface thereof, wherein the 3D pattern comprises a plurality of area enlarging elements configured to enlarge a total contact area of the interior surface with a precursor source stored therein;
heating the precursor source container to evaporate the precursor source to form a precursor vapor comprising a mixture of the carrier gas and the evaporated precursor source; and
transferring the precursor vapor to a deposition chamber.

19. The method of claim 18, further comprising:
adjusting a temperature of the precursor source container in situ based on an instruction to maintain a concentration of the precursor vapor in the precursor source container within a target range.

20. The method of claim 18, further comprising:
forming a layer of the precursor source on a substrate in the deposition chamber.

21. A method of thin film deposition using a precursor supply system, the precursor supply system comprising a precursor source container, wherein the precursor source container comprises: a top wall, a bottom wall, a side wall, an inlet and an outlet, the side wall circumferentially connecting the top wall and the bottom wall, and at least a portion of an interior surface of the precursor source container having a three-dimensional (3D) pattern; and, wherein the method comprises:
allowing introduction of a carrier gas into the precursor source container through the inlet; and
allowing exit of a precursor vapor generated in the precursor source container through the outlet.

22. The method of claim 21, wherein the 3D pattern is located on at least a portion of the bottom wall, or at least a portion of the top wall, or at least a portion of the side wall, or any combinations thereof.

23. The method of claim 21, wherein the 3D pattern comprises a plurality of area enlarging elements configured to enlarge a total contact area of the interior surface of the precursor source container with a precursor source stored therein.

24. The method of claim 23, wherein the area enlarging elements increase a total area of the interior surface by at least 10%, or at least 20%, or at least 30%, or at least 40%, or at least 50%, or at least 100%, or at least 150%, or at least 200%, or at least 500%, or at least 1,000%, relative to the interior surface without the area enlarging elements.

25. The method of claim 21, the precursor supply system further comprising a heating element in proximity or contact with the precursor source container; and, wherein the method further comprises: heating the precursor source container and evaporate a precursor source placed therein through the heating element.

26. The method of claim 25, the precursor supply system further comprising a precursor control unit operably connected to the precursor source container, the precursor control unit comprising: a concentration sensor, a temperature sensor, a mass sensor, and a temperature sensor operably connected to the heating element; and, wherein the method further comprises:
detecting and monitoring, through the concentration sensor, a real-time precursor vapor concentration in the precursor source container;
detecting and monitoring, through the temperature sensor, a real-time temperature of the precursor source container;
detecting and monitoring, through the mass sensor, a real-time unconsumed quantity of the precursor source remaining in the precursor source container; and
controlling, through the temperature sensor, the heating element and adjust the temperature of the precursor source container in situ during operation.

27. The method of claim 26, wherein the precursor control unit further comprises: a communication component; and, wherein the method further comprises through the communication component:
transmitting the real-time temperature, concentration of the precursor vapor, and/or unconsumed quantity of the precursor source to a computing system in situ during operation; and
receiving an instruction from the computing system, the instruction having a real-time temperature adjustment signal based on a pre-established operation model for a target range of the precursor vapor concentration,
controlling the heating element in situ is based on the instruction to maintain the precursor vapor concentration in the target range.

28. The method of claim 25, the precursor supply system further comprising a carrier gas source in gas communication with the inlet of the precursor source container; and wherein the method further comprises:
supplying, through the carrier gas source, a carrier gas into the precursor source container, wherein the carrier gas is mixed with the evaporated precursor source to generate a precursor vapor in the precursor source container.

29. The method of claim 28, the precursor supply system further comprising a mass flow controller in gas communication with the carrier gas source and the inlet of the precursor source container; and, wherein the method further comprises: controlling, through the mass flow controller, a flow rate and pressure of the carrier gas to be introduced into the precursor source container.

30. The method of claim 21, the precursor supply system further comprising a gas box in gas communication with the outlet of the precursor source container; and, wherein the method further comprises, through the gas box, stabilizing purifying, and homogenizing the precursor vapor transferred therein.
